(19) United States
(12) Patent Application Publication
(10) Pub. No.: US 2025/0132775 A1
(43) Pub. Date: Apr. 24, 2025

(54) RADIO FREQUENCY INTEGRATED CIRCUIT AND WIRELESS COMMUNICATION DEVICE INCLUDING THE SAME

(71) Applicant: Samsung Electronics Co., Ltd., Suwon-si (KR)

(72) Inventors: Sangwook HAN, Suwon-si (KR); Kyoungmin LEE, Suwon-si (KR); Kyungsoo LEE, Suwon-si (KR); Junho HUH, Suwon-si (KR)

(73) Assignee: Samsung Electronics Co., Ltd., Suwon-si (KR)

(21) Appl. No.: 18/768,569

(22) Filed: Jul. 10, 2024

(30) Foreign Application Priority Data
Oct. 19, 2023 (KR) 10-2023-0140608
Nov. 3, 2023 (KR) 10-2023-0151028

(51) Int. Cl. H04B 1/00; H03F 3/19

(52) U.S. Cl. CPC H04B 1/005; H03F 3/19; H03F 2200/294; H03F 2200/451

(57) ABSTRACT

A radio frequency integrated circuit (RFIC) includes a first receive chain configured to receive a first high-frequency input signal, generate a first baseband signal based on the first high-frequency input signal by using a first downward frequency signal, and output the first baseband signal to a first output port, a first local oscillator configured to generate a first oscillation clock signal, a second local oscillator configured to generate a second oscillation clock signal, a first multiplexer configured to output one among the first and oscillation clock signals to a second output port based on an oscillation clock output selection signal, a first input port configured to receive a third oscillation clock signal from an external source, and a second multiplexer configured to output one among the first through third oscillation signals to the first receive chain as the first downward frequency signal based on a first downward frequency selection signal.

### CROSS-REFERENCE TO RELATED APPLICATIONS

This application is based on and claims priority under 35 U.S.C. § 119 to Korean Patent Application Nos. 10-2023-0140608, filed on Oct. 19, 2023, and 10-2023-0151028, filed on Nov. 3, 2023, in the Korean Intellectual Property Office, the disclosures of which are incorporated by reference herein in their entireties.

### BACKGROUND

The inventive concepts relate to a radio frequency integrated circuit (RFIC) for processing a high-frequency signal and a wireless communication device including the same, and more particularly, to an RFIC, which outputs an oscillation clock signal, and a wireless communication device capable of allowing an oscillation clock signal to be shared by a plurality of RFICs in a package including a modem chip and the RFICs.

Wireless communication devices usually include an RFIC, which receives a high-frequency signal (e.g., an RF signal) through an antenna and converts the high-frequency signal into a baseband signal, and a modem chip, which receives the baseband signal from the RFIC, converts the baseband signal into a digital signal, and processes the digital signal. Each of the modem chip and the RFIC is packaged and mounted on a system printed circuit board (PCB). The modem chip and the RFIC exchange baseband signals with each other through wires formed on the system PCB.

An RFIC of the fifth generation (5G) Frequency Range 1 (FR1) may include a plurality of receive chains to support multimode (2G/3G/4G) and various frequency bands including 6 GHz or less and implement various types of carrier aggregations (CA). As wireless communication devices require (or utilize) an increasing number of various types of CA, the number of receive chains of an RFIC also increases. Since one local oscillator typically corresponds to one receive chain, many local oscillators are required (or used) to support various types of CA, thereby increasing the burden of producing a new RFIC.

### SUMMARY

The inventive concepts provide a wireless communication device capable of responding to various carrier aggregation (CA) scenarios without designing a new radio frequency integrated circuit (RFIC) by allowing an oscillation clock signal to be shared by RFICs.

According to an aspect of the inventive concepts, there is provided an RFIC including a first receive chain configured to receive a first high-frequency input signal, generate a first baseband signal based on the first high-frequency input signal by using a first downward frequency signal, and output the first baseband signal to a first output port, a first local oscillator configured to generate a first oscillation clock signal, a second local oscillator configured to generate a second oscillation clock signal, a first multiplexer configured to output one among the first oscillation clock signal or the second oscillation clock signal to a second output port based on an oscillation clock output selection signal, a first input port configured to receive a third oscillation clock signal from an external source, and a second multiplexer configured to output one among the first oscillation signal, the second oscillation signal or the third oscillation signal to the first receive chain as the first downward frequency signal based on a first downward frequency selection signal.

According to an aspect of the inventive concepts, there is provided a wireless communication device including a first radio frequency integrated circuit (RFIC), a second RFIC, and a modem chip, wherein each of the first RFIC and the second RFIC includes a first receive chain configured to receive a first high-frequency input signal, generate a first baseband signal based on the first high-frequency input signal by using a first downward frequency signal, and output the first baseband signal to the modem chip through a first output port of the first receive chain, a second receive chain configured to receive a second high-frequency input signal, generate a second baseband signal based on the second high-frequency input signal by using a second downward frequency signal, and output the second baseband signal to the modem chip through a second output port of the second receive chain, a first local oscillator configured to generate a first oscillation clock signal, a second local oscillator configured to generate a second oscillation clock signal, a first multiplexer configured to output one among the first oscillation clock signal and the second oscillation clock signal to a third output port based on an oscillation clock output selection signal, a first input port configured to receive a third oscillation clock signal from the modem chip, a second multiplexer configured to output one among the first oscillation signal, the second oscillation signal or the third oscillation signal to the first receive chain based on a first downward frequency selection signal, and a third multiplexer configured to output one among the first oscillation signal, the second oscillation signal or the third oscillation signal to the second receive chain based on a second downward frequency selection signal, the modem chip includes a first oscillation clock input port, a first wire, a first oscillation clock output port, a second oscillation clock input port, a second wire, and a second oscillation clock output port, and an oscillation clock signal output from the third output port of the first RFIC is input as the third oscillation clock signal to the first input port of the second RFIC through the first oscillation clock input port, the first wire and the first oscillation clock output port.

According to an aspect of the inventive concepts, there is provided an operating method of a wireless communication device including a first RFIC, a second RFIC and a modem chip. The operating method includes generating, by the first RFIC, a first oscillation clock signal, generating, by the second RFIC, a second oscillation clock signal, outputting, by the second RFIC, the second oscillation clock signal to the modem chip, outputting, by the modem chip, the second oscillation clock signal to the first RFIC through a wire of the modem chip, converting, by the first RFIC, a first high-frequency input signal into a first baseband signal by using the first oscillation clock signal, and converting, by the first RFIC, a second high-frequency input signal a second baseband signal by using the second oscillation clock signal received from the modem chip, the first RFIC and the second RFIC being stacked on the modem chip.

### BRIEF DESCRIPTION OF THE DRAWINGS

Embodiments will be more clearly understood from the following detailed description taken in conjunction with the accompanying drawings in which:

FIG. 1 is a block diagram of a radio frequency integrated circuit (RFIC) according to embodiments;

FIG. 2 illustrates example types of carrier aggregation (CA);

FIG. 3 illustrates inter-band CA using three frequency bands;

FIG. 4 is a block of a wireless communication device including the RFIC of FIG. 1 and a modem chip;

FIGS. 5A and 5B illustrate packages including the wireless communication device of FIG. 4;

FIG. 6 is a block diagram of a wireless communication device including three RFICs and a modem chip, according to embodiments;

FIG. 7 illustrates a package including the wireless communication device of FIG. 6; and

FIG. 8 is a flowchart showing operations of a wireless communication device, according to embodiments.

### DETAILED DESCRIPTION

Hereinafter, embodiments are described in detail with reference to the accompanying drawings.

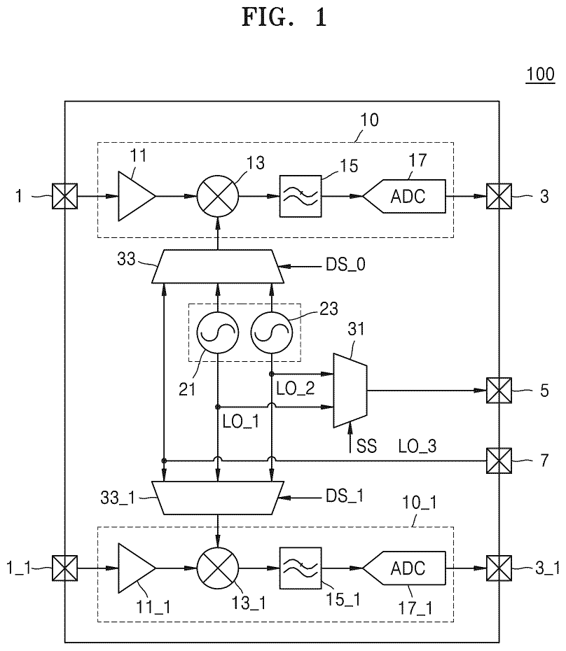

FIG. 1 is a block diagram of a radio frequency integrated circuit (RFIC) according to embodiments. Referring to FIG. 1, an RFIC 100 may include input/output ports, local oscillators, multiplexers, and first and second receive chains.

The input/output ports may include high-frequency signal input ports (e.g., 1 and 1_1), baseband signal output ports (e.g., 3 and 3_1), an oscillation clock output port 5 (may also be referred to herein as the third output port 5), and/or an oscillation clock input port 7 (may also be referred to herein as the third input port 7). Hereinafter, a port generally refers to a unit for inputting a signal into a semiconductor chip or outputting a signal of the semiconductor chip and may also be called a terminal.

The high-frequency signal input ports may include a first input port 1 and a second input port 1_1. The first input port 1 may receive a first high-frequency input signal from the outside of the RFIC 100 and transmit (or pass) the first high-frequency input signal to a corresponding receive chain. The second input port 1_1 may receive a second high-frequency input signal from the outside of the RFIC 100 and transmit (or pass) the second high-frequency input signal to a corresponding receive chain. The first and second high-frequency input signals may each have a carrier frequency in a different frequency band (e.g., the first high-frequency input signal may have a carrier frequency in a different frequency band from a carrier frequency of the second high-frequency input signal). The baseband signal output ports may include a first output port 3 and a second output port 3_1. The first output port 3 may transmit (or pass) a first baseband signal, which is generated from the first high-frequency input signal by a first receive chain 10, to the outside of the RFIC 100. The second output port 3_1 may transmit a second baseband signal, which is generated from the second high-frequency input signal by a second receive chain 10_1, to the outside of the RFIC 100. A baseband signal may include an analog signal or a digital signal. Although the case where a receive chain outputs a baseband digital signal to the outside of the RFIC 100 is described as an example in embodiments, a baseband analog signal may be output from the RFIC 100.

Local oscillators may include a first local oscillator 21 and/or a second local oscillator 23. The first local oscillator 21 may generate a first oscillation clock signal LO_1 having a first frequency and the second local oscillator 23 may generate a second oscillation clock signal LO_2 having a second frequency. The first frequency may be included in a first frequency band. The second frequency may be included in a second or third frequency band that is different from the first frequency band. The first frequency band may correspond to a low band between, for example, 0.5 GHz and 1 GHz. A second frequency band may correspond to a middle band between, for example, 1.4 GHz and 2 GHz, and a third frequency band may correspond to a high band between, for example, 2.3 GHz and 2.7 GHZ. The second local oscillator 23 may generate a frequency in either the second frequency band or the third frequency band as the second frequency according to a set signal.

Although not shown, a local oscillator (e.g., 21 or 23) usually includes a phase detector, a charge pump, a voltage controlled oscillator (VCO), and/or a divider, and may adjust the frequency of an oscillation clock signal by adjusting the division factor of the divider.

The third input port 7 corresponding to an oscillation clock input port may receive a third oscillation clock signal LO_3 having a third frequency from the outside of the RFIC 100. The third frequency may be included in either the second frequency band or the third frequency band. When the second oscillation clock signal LO_2 generated by the second local oscillator 23 is included in the second frequency band, the third oscillation clock signal LO_3 input to the third input port 7 may have the third frequency in the third frequency band.

The multiplexers may include first to third multiplexers 31, 33, and 33_1. The first multiplexer 31 may receive the first oscillation clock signal LO_1 from the first local oscillator 21 and the second oscillation clock signal LO_2 from the second local oscillator 23, and transmit one of the first and second oscillation clock signals LO_1 and LO_2 (e.g., either the first oscillation clock signal LO_1 or the second oscillation clock signal LO_2) to the third output port 5, which corresponds to an oscillation clock output port, in response to an oscillation clock output selection signal SS. The oscillation clock output selection signal SS may be set according to carrier aggregation (CA) information that is determined according to the communication environment of a wireless communication device including a modem chip connected to the RFIC 100.

The second multiplexer 33 may receive the first oscillation clock signal LO_1, the second oscillation clock signal LO_2, and the third oscillation clock signal LO_3, which is input through the third input port 7 corresponding to an oscillation clock input port, and transmit one of the first to third oscillation clock signals LO_1, LO_2, and LO_3 (e.g., only one among the first oscillation clock signal LO_1, the second oscillation clock signal LO_2 or the third oscillation clock signal LO_3) as a first downward frequency signal in response to a first downward frequency selection signal DS_0.

The third multiplexer 33_1 may receive the first oscillation clock signal LO_1, the second oscillation clock signal LO_2, and the third oscillation clock signal LO_3, which is input through the third input port 7 corresponding to an oscillation clock input port, and transmit one of the first to third oscillation clock signals LO_1, LO_2, and LO_3 (e.g., only one among the first oscillation clock signal LO_1, the second oscillation clock signal LO_2 or the third oscillation clock signal LO_3) as a second downward frequency signal in response to a second downward frequency selection signal DS_1. An oscillation clock signal selected by the second multiplexer 33 may have a different frequency than an oscillation clock signal selected by the third multiplexer 33_1. The first and second downward frequency selection signals DS_0 and DS_1 may also be set according to CA information that is determined according to the communication environment of a wireless communication device including a modem chip connected to the RFIC 100.

The first receive chain 10 may include a low-noise amplifier 11, a mixer 13, a low-pass filter 15, and/or an analog-to-digital converter (ADC) 17. The low-noise amplifier 11 may receive the first high-frequency input signal from the first input port 1 and generate an amplified first high-frequency signal by amplifying the first high-frequency input signal. The mixer 13 may mix the amplified first high-frequency signal from the low-noise amplifier 11 with the first downward frequency signal from the second multiplexer 33, thereby generating a first baseband analog signal. The low-pass filter 15 may remove a noise component from the first baseband analog signal output from the mixer 13. The ADC 17 may convert a noise-removed first baseband analog signal into a first digital signal and transmit the first digital signal to the first output port 3.

The second receive chain 10_1 may include a low-noise amplifier 11_1, a mixer 13_1, a low-pass filter 15_1, and/or an ADC 17_1. The low-noise amplifier 11_1 may receive the second high-frequency input signal from the second input port 1_1 and generate an amplified second high-frequency signal by amplifying the second high-frequency input signal. The mixer 13_1 may mix the amplified second high-frequency signal from the low-noise amplifier 11_1 with the second downward frequency signal from the third multiplexer 33_1, thereby generating a second baseband analog signal. The low-pass filter 15_1 may remove a noise component from the second baseband analog signal output from the mixer 13_1. The ADC 17_1 may convert a noise-removed second baseband analog signal into a second digital signal and transmit the second digital signal to the second output port 3_1.

Each of the ADC 17 of the first receive chain 10 and the ADC 17_1 of the second receive chain 10_1 may have a resolution of about 9 bits to about 11 bits, and accordingly, each of the first and second output ports 3 and 3_1 may include multiple output terminals. Each of the first and second receive chains 10 and 10_1 may not include the ADC 17 or 17_1, and may transmit a baseband analog signal, which has passed through the low-pass filter 15 or 15_1, to the first or second output port 3 or 3_1. Each of the first and second receive chains 10 and 10_1 may further include a balun (not shown) between the low-noise amplifier 11 or 11_1 and the mixer 13 or 13_1 to generate a differential signal for robust signal processing.

For example, the case where the second local oscillator 23 generates the second oscillation clock signal LO_2 having the second frequency in the middle band such that the RFIC 100 supports inter-band CA by simultaneously (or contemporaneously) processing a midband high-frequency input signal by using the first receive chain 10 and a highband high-frequency input signal by using the second receive chain 10_1 is described.

The RFIC 100 may receive the third oscillation clock signal LO_3 having the third frequency in the high band from the outside thereof through the third input port 7 corresponding to an oscillation clock input port. The second multiplexer 33 may transmit, as the first downward frequency signal, the second oscillation clock signal LO_2, which is generated by the second local oscillator 23, to the mixer 13 in response to the first downward frequency selection signal DS_0. The third multiplexer 33_1 may transmit, as the second downward frequency signal, the third oscillation clock signal LO_3, which is received from the outside, to the mixer 13_1 in response to the second downward frequency selection signal DS_1. The RFIC 100 may enable the first local oscillator 21 to generate the first oscillation clock signal LO_1 having the first frequency corresponding to the low band and may output the first oscillation clock signal LO_1 having the first frequency or the second oscillation clock signal LO_2 having the second frequency through the third output port 5 in response to the oscillation clock output selection signal SS.

According to embodiments, the RFIC 100 may use oscillation clock signals (e.g., LO_1 and LO_2), which are generated by local oscillators inside the RFIC 100, and an oscillation clock signal (e.g., LO_3), which is received from the outside of the RFIC 100, as downward frequency signals for a mixer of a receive chain, thereby efficiently responding to various CA scenarios required (or encountered) by a wireless communication device, without increasing the number of local oscillators in the RFIC 100.

In the example described above, the RFIC 100 may communicate with another RFIC and exchange at least one oscillation clock signal with another RFIC. According to embodiments, a wireless communication device may include at least two RFICs, which may correspond to semiconductor chips or dies respectively manufactured through different semiconductor processes. Various packaging methods may be applied to RFICs and a modem chip, which are included in a wireless communication device. Although examples below illustrate the case where all RFICs are mounted on a single package, embodiments are not limited thereto.

Although it has been described that an RFIC includes a local oscillator related to the low band and a local oscillator related to the mid-high band, embodiments are not limited to. For example, an RFIC may include local oscillators related to various bands. When an RFIC includes at least one local oscillator related to only the middle-high band, a wireless communication device may be configured to receive an oscillation clock signal related to the low band from the outside.

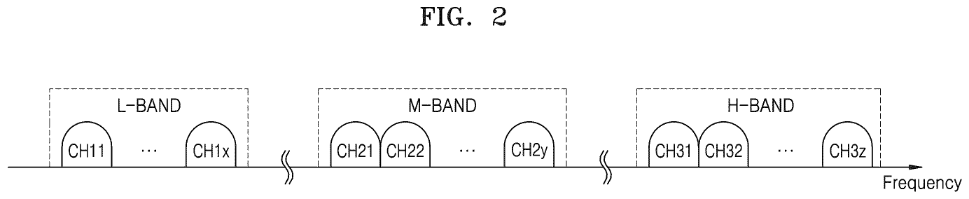

FIG. 2 illustrates a CA method using frequency channels (or carriers) in three frequency bands. Using three frequency bands (e.g., L-BAND, M-BAND, and H-BAND) in FIG. 2 is just an example for clear understanding, but embodiments are not limited thereto. It will be apparent that the inventive concepts may be applied to a method of using less or more bands.

A low band L-BAND may be between 0.5 GHz and 1 GHZ, and may include frequency channels CH11 to CH1x. A middle band M-BAND may be between 1.4 GHz and 2 GHZ, and may include frequency channels CH21 to CH2y. A high band H-BAND may be between 2.3 GHz and 4.7 GHZ, and may include frequency channels CH31 to CH3z. Each frequency band may have a frequency range that meets a communication standard (e.g., a communication standard related to fifth generation (5G) New Radio (NR) of the 3^{rd} Generation Partnership Project (3GPP)).

CA may include intra-band CA that aggregates frequency channels in different frequency bands, contiguous inter-band CA that aggregates contiguous frequency channels in the same frequency band (or similar frequency bands), and non-contiguous inter-band CA that aggregates frequency channels which are not contiguous in the same band (or similar bands).

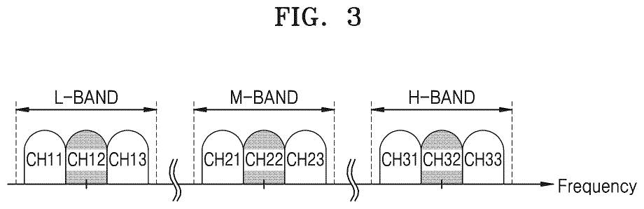

FIG. 3 illustrates inter-band CA using the frequency bands in FIG. 2. Referring to FIGS. 1 and 3, when the RFIC 100 processes the frequency channel CH22 in the middle band M-BAND through the first receive chain 10 and the frequency channel CH32 in the high band H-BAND through the second receive chain 10_1, the first receive chain 10 of the RFIC 100 may generate a first baseband signal from the signal of the frequency channel CH22 by using a midband oscillation clock signal, e.g., the second oscillation clock signal LO_2, which is generated by the second local oscillator 23, and generate a second baseband signal from the signal of the frequency channel CH32 by using a highband oscillation clock signal, e.g., the third oscillation clock signal LO_3, which is received from the outside through the third input port 7.

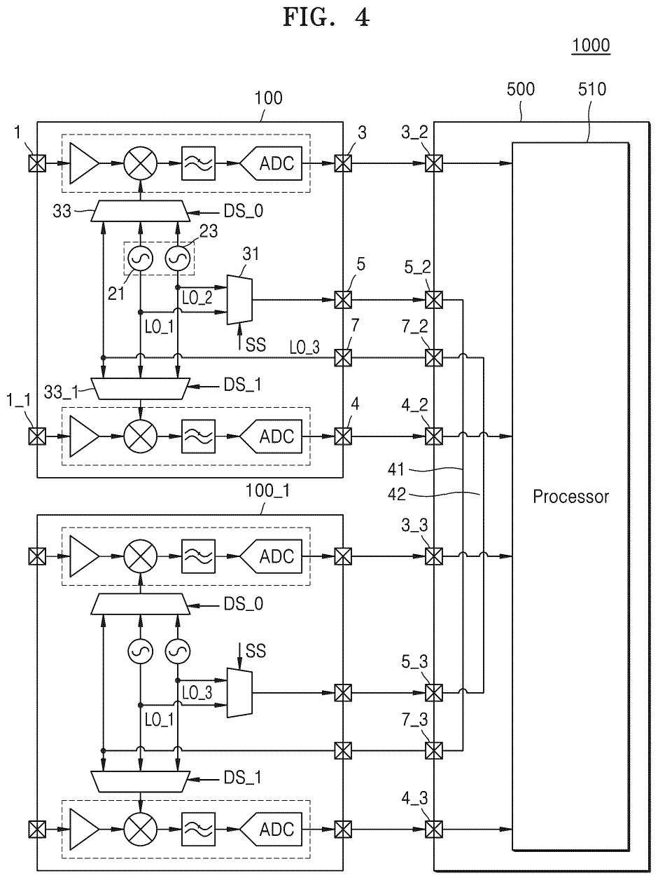

FIG. 4 is a block of a wireless communication device which includes a plurality of RFICs and a modem chip. Although the case where a wireless communication device includes two RFICs is illustrated in FIG. 4, the number of RFICs included in the wireless communication device is not limited thereto.

Referring to FIG. 4, a wireless communication device 1000 may include a first RFIC 100, a second RFIC 100_1, and/or a modem chip 500. The first RFIC 100 and the second RFIC 100_1 may each have the same structure as (or a similar structure to) the RFIC 100 of FIG. 1, and thus, redundant descriptions and reference characters thereof are omitted.

The modem chip 500 may include input ports 3_2, 4_2, 3_3, and 4_3 each receiving a baseband signal from the first or second RFIC 100 or 100_1, oscillation clock input ports 5_2 and 5_3 respectively receiving oscillation clock signals respectively from the first or second RFIC 100 or 100_1, oscillation clock output ports 7_2 and 7_3 respectively transmitting (or passing) oscillation clock signals to the first or second RFIC 100 or 100_1, first and second wires 41 and 42, and a processor 510.

The baseband signals received through the input ports 3_2, 4_2, 3_3, and 4_3 may be input to the processor 510, demodulated, and then undergo signal processing. When a baseband signal input to each input port is a digital signal, a digital filter may be further provided between the input port and the processor 510. According to embodiments, the signal processing performed by the processor 510 may include, for example, providing the demodulated baseband signal to a corresponding application executing on the wireless communication device 1000, storing the demodulated baseband signal (e.g., in a memory of the modem chip 500), sending a response signal responding to information contained in the demodulated baseband signal, etc.

The oscillation clock input port 5_2 may be connected to the oscillation clock output port 7_3 through the first wire 41 in the modem chip 500. An oscillation clock signal, which is transmitted from the oscillation clock output port 5 of the first RFIC 100 and input to the oscillation clock input port 5_2 of the modem chip 500, may be transmitted (or passed) to the oscillation clock input port 7 of the second RFIC 100_1 through the first wire 41 and the oscillation clock output port 7_3.

The oscillation clock input port 5_3 may be connected to the oscillation clock output port 7_2 through the second wire 42 in the modem chip 500. An oscillation clock signal, which is transmitted from the oscillation clock output port 5 of the second RFIC 100_1 and input to the oscillation clock input port 5_3 of the modem chip 500, may be transmitted (or passed) to the oscillation clock input port 7 of the first RFIC 100 through the second wire 42 and the oscillation clock output port 7_2. In embodiments, when a buffer circuit that buffers an oscillation clock signal is further included in the modem chip 500, the magnitude of the oscillation clock signal may be prevented from decreasing (or an amount or frequency of occurrence of such a decrease may be reduced).

The modem chip 500 may transmit at least one control signal to each RFIC such that operation or non-operation of a local oscillator of the RFIC, the oscillation clock output selection signal SS, and/or the first and second downward frequency selection signals DS_0 and DS_1 are set based on various scenarios supporting a CA type according to a communication state. For example, the case where the first receive chain 10 of the first RFIC 100 processes a midband high-frequency signal, the second receive chain 10_1 of the first RFIC 100 processes a highband high-frequency signal, and the modem chip 500 processes inter-band CA is described.

The second local oscillator 23 of the first RFIC 100 may generate the second oscillation clock signal LO_2 having the second frequency in the middle band and the second local oscillator 23 of the second RFIC 100_1 may generate the third oscillation clock signal LO_3 having the third frequency in the high band. The first multiplexer 31 of the second RFIC 100_1 may output, to the oscillation clock output port 5, the third oscillation clock signal LO_3 among the first oscillation clock signal LO_1, which is generated by the first local oscillator 21 and has the first frequency, and the third oscillation clock signal LO_3, which is generated by the second local oscillator 23 and has the third frequency, in response to the oscillation clock output selection signal SS (generated and transmitted by the modem chip 500, e.g., by the processor 510 of the model chip 500).

The third oscillation clock signal LO_3 may be output from the second RFIC 100_1, then input to the oscillation clock input port 5_3 of the modem chip 500, and then transmitted (or passed) to the oscillation clock input port 7 of the first RFIC 100 through the second wire 42 and the oscillation clock output port 7_2 of the modem chip 500.

The third oscillation clock signal LO_3, which has the third frequency and is input to the first RFIC 100, may be transmitted (or passed) to the second and third multiplexers 33 and 33_1 of the first RFIC 100. The second multiplexer 33 of the first RFIC 100 may select and transmit the second oscillation clock signal LO_2, which has the second frequency, as the first downward frequency signal to the mixer 13 in response to the first downward frequency selection signal DS_0 (generated and transmitted by the modem chip 500, e.g., by the processor 510 of the model chip 500). The third multiplexer 33_1 of the first RFIC 100 may select and transmit the third oscillation clock signal LO_3, which has the third frequency, as the second downward frequency signal to the mixer 13_1 in response to the second downward frequency selection signal DS_1 (generated and transmitted by the modem chip 500, e.g., by the processor 510 of the model chip 500).

The first receive chain 10 of the first RFIC 100 may convert the first high-frequency input signal into the first baseband analog signal by using the second oscillation clock signal LO_2, which has the second frequency and is input to the mixer 13 as the first downward frequency signal. The mixer 13_1 of the second receive chain 10_1 of the first RFIC 100 may convert the second high-frequency input signal into the second baseband analog signal by using the third oscillation clock signal LO_3, which has been generated by the second RFIC 100_1 and transmitted through the modem chip 500 and has the third frequency in the high band, as the second downward frequency signal.

According to the example described above, the number of local oscillators of each RFIC may be less than the number of frequency bands in which signal processing is possible in the RFIC. When the number of RFICs sharing an oscillation clock signal increases, the number of frequency bands that may be supported by each RFIC may also increase or the number of local oscillators of each RFIC may decrease. As a result, the cost of implementing an RFIC or the area of an RFIC may be decreased.

The modem chip 500, the first RFIC 100, and the second RFIC 100_1, which form the wireless communication device 1000 of FIG. 4, may be arranged in a single package and may interface a baseband signal and an oscillation clock signal in the package. Hereinafter, it may be generally considered that a package includes at least one or two semiconductor chips, an interface unit for signal transmission between a semiconductor chip inside the package and a semiconductor chip outside the package, and an interface unit for signal transmission between the semiconductor chips inside the package and performs a function of protecting the semiconductor chips from an external environment.

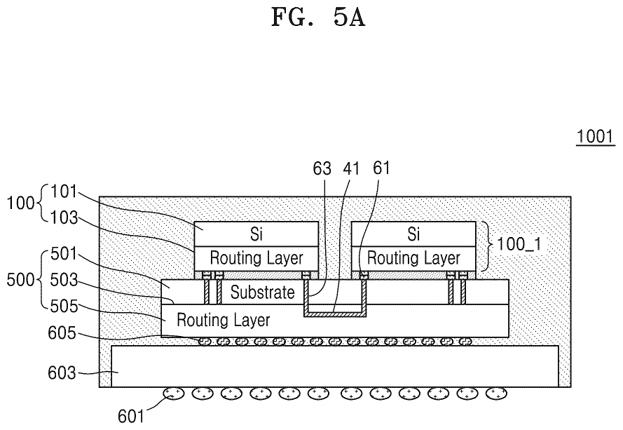

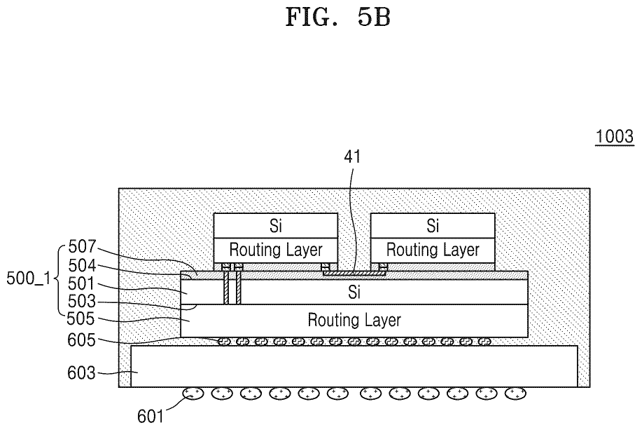

FIGS. 5A and 5B illustrate packages each including a wireless communication device. Referring to FIGS. 4 and 5A, a package 1001 may include package balls 601, a package printed circuit board (PCB) 603, microballs 605, the modem chip 500, the first RFIC 100, and the second RFIC 100_1. Each of the first and second RFICs 100 and 100_1 may exchange high-frequency signals with an RF front-end module (RFFEM) outside the package 1001 through the package balls 601, the package PCB 603, and the microballs 605.

The modem chip 500 may include a first substrate 501, in which a circuit such as the processor 510 is formed, and a routing layer 505, which is formed on a first surface 503 of the first substrate 501. Each of the first and second RFICs 100 and 100_1 may include a second substrate 101, in which the circuits described with reference to FIG. 4 are formed, and a routing layer 103. At least one of the oscillation clock signals generated by the first RFIC 100 may be transmitted to the second RFIC 100_1 through chip-to-chip (C2C) bonding pads 61 between the first and second RFICs 100 and 100_1 and the modem chip 500, through silicon vias (TSVs) 63 penetrating the first substrate 501 of the modem chip 500, and the first wire 41 formed in the routing layer 505 of the modem chip 500. The first and second RFICs 100 and 100_1 may communicate with the modem chip 500 according to various connection units. Hybrid copper bonding (HCB) may be used as an example of bonding.

At least one of the oscillation clock signals generated by the second RFIC 100_1 may be transmitted to the first RFIC 100 in the same manner as (or a similar manner to) that described above. Although not shown in FIGS. 5A and 5B for convenience of description, the second wire 42 in FIG. 4 may also be formed in the routing layer 505 of the modem chip 500 and thus be used for transmission of an oscillation clock signal between the first and second RFICs 100 and 100_1. When wires are formed in the routing layer 505 of the modem chip 500, a plurality of metal layers may be arranged in the routing layer 505 and at least one oscillation clock signal may be transmitted through wires formed in the metal layers. Baseband signals may be transmitted between each of the first and second RFICs 100 and 100_1 and the modem chip 500 through the TSVs 63 penetrating the first substrate 501 of the modem chip 500.

Referring to FIGS. 4 and 5B, a package 1003 of FIG. 5B has the same structure as (or a similar structure to) the package 1001 of FIG. 5A, except for the position of the first wire 41 that transmits (or passes) an oscillation clock signal between RFICs, and thus, reference characters of like elements are omitted.

A modem chip 500_1 may include the first substrate 501, the routing layer 505 on the first surface 503 of the first substrate 501, and a redistribution layer 507 on a second surface 504 of the first substrate 501. In the wireless communication device of the package 1003, at least one of the oscillation clock signals generated by the first RFIC 100 may be transmitted to the second RFIC 100_1 through the C2C bonding pads 61 between the first and second RFICs 100 and 100_1 and the modem chip 500_1 and the first wire 41 formed in the redistribution layer 507.

An oscillation clock signal generated by an RFIC may have a frequency of up to 10 GHz and is the most important signal (or an important signal) for the performance of the RFIC and thus needs to (or should be configured to) maintain appropriate phase noise and jitter characteristics. In general wireless communication devices, in which a modem chip and RFICs are mounted on a system PCB and connected to each other, because of the large parasitic capacitance and the large parasitic resistance of the system PCB, it is hard to transmit a high-frequency oscillation clock signal between the RFICs through a wire formed in the system PCB while maintaining the appropriate phase noise and jitter characteristics. Moreover, the phase noise and jitter characteristics of the high-frequency oscillation clock signal may be further deteriorated due to interference between the wire and surrounding signal lines. Contrarily, in the packages 1001 and 1003, each of which has a three-dimensional (3D) shape and includes a wireless communication device according to embodiments, the high-frequency oscillation clock signal of an RFIC may be transmitted inside each of the packages 1001 and 1003 without wiring in a system PCB and may thus maintain its appropriate phase noise and jitter characteristics.

Although it is illustrated in FIGS. 5A and 5B that all RFICs of a wireless communication device are stacked on a modem chip and communicate with the modem chip through the same connection structure (or similar connection structures), packaging and communication may be performed using various methods according to embodiments. For example, at least one RFIC may be mounted on the package PCB 603 at the same height as (or a similar height to) a modem chip, and packaging may be performed according to various structures, such as a stack structure of at least two RFICs.

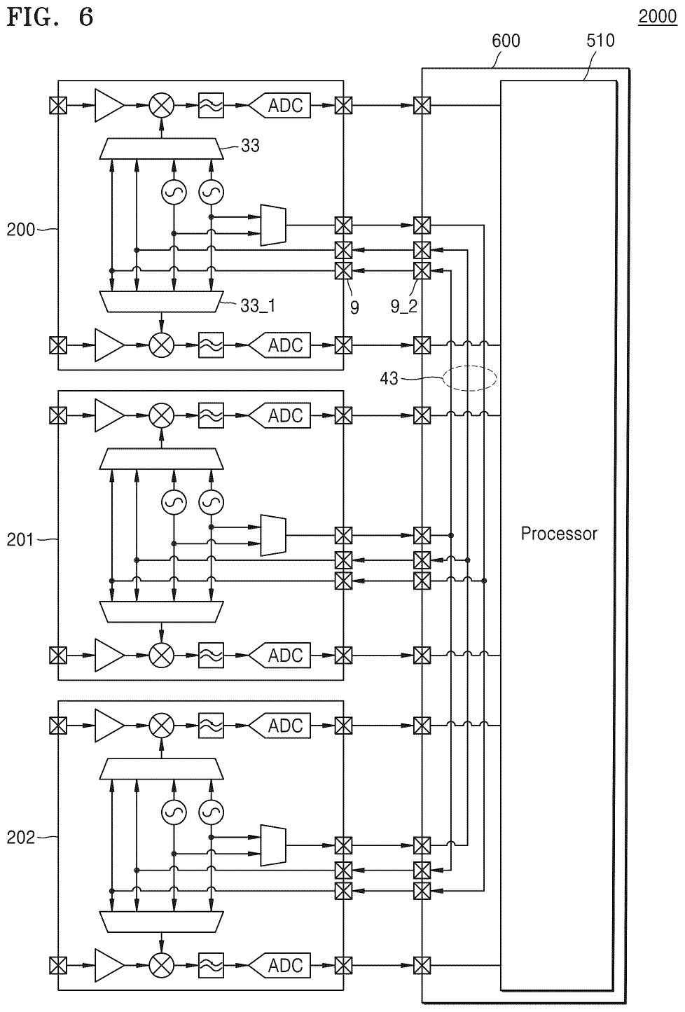

FIG. 6 is a block diagram of a wireless communication device including three RFICs and a modem chip, according to embodiments.

Referring to FIG. 6, a wireless communication device 2000 may include first to third RFICs 200, 201, and 202 and/or a modem chip 600. The modem chip 600 may be connected to each of the first to third RFICs 200, 201, and 202 and may include the processor 510. While two RFICs share an oscillation clock in the wireless communication device 1000 of FIG. 4, three RFICs share an oscillation clock in the wireless communication device 2000 of FIG. 6.

Each of the first to third RFICs 200, 201, and 202 of the wireless communication device 2000 may have the same structure as (or a similar structure to) the RFIC 100 in FIG. 4, except that an additional oscillation clock input signal is further input to each of the second multiplexer 33 and the third multiplexer 33_1, and an oscillation clock input port 9 is further provided. Compared to the modem chip 500 in FIG. 4, the modem chip 600 of the wireless communication device 2000 may further include an output port 9_2 which outputs an oscillation clock signal received from each of the first to third RFICs 200, 201, and 202. In addition, wires 43, which transmit oscillation clock signals in the modem chip 600, may further include at least one wire in addition to the first and second wires 41 and 42 in FIG. 4. An oscillation clock signal output from one of the first to third RFICs 200, 201, and 202 of the wireless communication device 2000 may be transmitted to the others of the first to third RFICs 200, 201, and 202 through the wires 43 formed in the modem chip 600. For example, an oscillation clock signal output from the first RFIC 200 may be transmitted to the second and third RFICs 201 and 202 through the wires 43 of the modem chip 600. An oscillation clock signal output from the second RFIC 201 may be transmitted to the first and third RFICs 200 and 202 through the wires 43 of the modem chip 600. An oscillation clock signal output from the third RFIC 202 may be transmitted to the first and second RFICs 200 and 201 through the wires 43 of the modem chip 600.

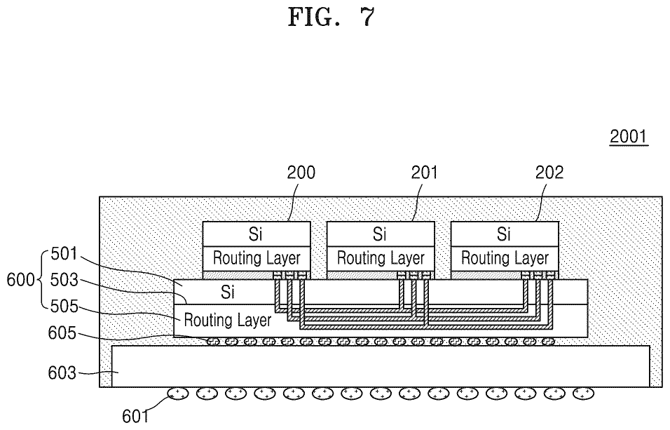

FIG. 7 illustrates a package including a wireless communication device. A package 2001 of FIG. 7 may have the same structures as (or similar structures to) the package 1001 of FIG. 5A, except that an additional RFIC is further provided on the modem chip 600 and an additional wire(s) for an oscillation clock signal is further provided in the routing layer 505 on the first surface 503 of the first substrate 501 of the modem chip 600. Although not shown, like the package 1003 of FIG. 5B, the package 2001 of FIG. 7 may be configured such that a redistribution layer is formed on the second surface of the first substrate 501 of the modem chip 600 and wires for oscillation clock transmission are arranged in the redistribution layer. Although it is illustrated in FIG. 7 that three RFICs (e.g., 200, 201, and 202) are stacked on the modem chip 600, more RFICs may be stacked on the modem chip 600.

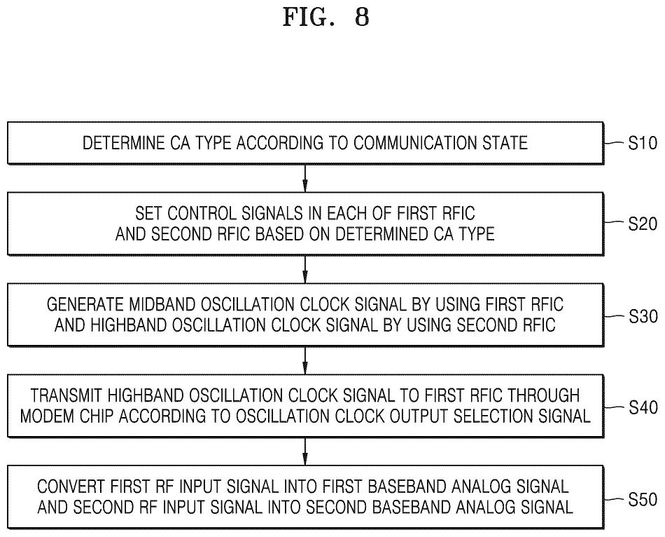

FIG. 8 is a flowchart of the operations of a wireless communication device in a single package, according to embodiments.

The operations of a wireless communication device are described with reference to FIGS. 4 and 8. The modem chip 500 may determine a CA type according to a communication state in operation S10. As described above with reference to FIG. 2, the CA type may include inter-band CA or intra-band CA, and the number of frequency channels used for CA. For example, depending on the communication state, the first RFIC 100 may be used to determine an inter-band 2CA using a first high-frequency input signal of the middle band and a second high-frequency input signal of the high band. The modem chip 500 may transmit a control signal(s) to each of the first and second RFICs 100 and 100_1 according to the determined CA type. In response to the control signal(s), each of the first and second RFICs 100 and 100_1 may set the oscillation clock output selection signal SS and the first and second downward frequency selection signals DS_0 and DS_1 in operation S20.

The second local oscillator 23 of the first RFIC 100 may generate a midband oscillation clock signal, e.g., the second oscillation clock signal LO_2, and the second local oscillator 23 of the second RFIC 100_1 may generate a highband oscillation clock signal, e.g., the third oscillation clock signal LO_3, in operation S30. The highband oscillation clock signal, e.g., the third oscillation clock signal LO_3, generated by the second RFIC 100_1 may be transmitted to the modem chip 500 through the first multiplexer 31 of the second RFIC 100_1 according to the oscillation clock output selection signal SS and then input to the oscillation clock input port 7 of the first RFIC 100 through the wire 42 and the oscillation clock output port 7_2 of the modem chip 500 in operation S40. The mixer 13 of the first receive chain 10 of the first RFIC 100 may receive the midband oscillation clock signal, e.g., the second oscillation clock signal LO_2, from the second multiplexer 33 of the first RFIC 100 and convert the first high-frequency input signal into a first baseband analog signal in operation S50. The mixer 13_1 of the second receive chain 10_1 of the first RFIC 100 may receive the highband oscillation clock signal, e.g., the third oscillation clock signal LO_3, from the modem chip 500 through the third multiplexer 33_1 of the first RFIC 100 and convert the second high-frequency input signal into a second baseband analog signal in operation S50.

As described above, a wireless communication device may be configured with a modem chip and RFICs in a 3D package such that at least one of the oscillation clock signals generated by a local oscillator of each of the RFICs is shared with the other RFICs. Accordingly, RFIC resources may be efficiently utilized in various scenarios, such as CA and multiple-input and multiple-output (MIMO) of the wireless communication device.

Conventional devices and methods for performing wireless communication include radio frequency integrated circuits (RFICs) for converting signals between higher transmission frequencies and a lower baseband frequencies. RFICs of the conventional devices and methods include a separate local oscillator for each receive chain. To enable various modes of communication (e.g., communication with 2G networks, 3G networks, 4G networks, etc., communication with various frequency bands, communication via various types of carrier aggregations (CA), etc.) the quantity of receive chains and local oscillators are increased in the conventional devices and methods. Such an increase in receive chains and local oscillators results in excessive manufacturing costs and RFIC size (e.g., excessive physical area of the RFIC).

However, according to embodiments, improved devices and methods are provided for performing wireless communication. For example, the improved devices and methods may include RFICs capable of sharing one or more local oscillator signals between one another. Accordingly, the quantity of local oscillator frequencies available for use on a respective RFIC of the improved devices and methods is not limited to the quantity of local oscillators on the RFIC. Thus, the improved devices and methods are able to enable various modes of communication (e.g., communication with 2G networks, 3G networks, 4G networks, etc., communication with various frequency bands, communication via various types of carrier aggregations (CA), etc.) without increasing the quantity of receive chains or local oscillators in the RFICs. Therefore, the improved devices and methods overcome the deficiencies of the conventional devices and methods to at least increase the versatility of RFICs while avoiding (or reducing) the increases in manufacturing costs and RFIC size (e.g., excessive physical area of the RFIC) of the conventional devices and methods.

According to embodiments, operations described herein as being performed by the RFIC 100 (e.g., the first RFIC 100), the first receive chain 10, the second receive chain 10_1, the first local oscillator 21, the second local oscillator 23, the phase detector of the first local oscillator 21 and/or the second local oscillator 23, the charge pump of the first local oscillator 21 and/or the second local oscillator 23, the VCO of the first local oscillator 21 and/or the second local oscillator 23, the divider of the first local oscillator 21 and/or the second local oscillator 23, each of the first to third multiplexers 31, 33, and 33_1, the low-noise amplifier 11, the mixer 13, the low-pass filter 15, the ADC 17, the low-noise amplifier 11_1, the mixer 13_1, the low-pass filter 15_1, the ADC 17_1, the balun(s) of the first receive chain 10 and/or the second receive chain 10_1, the wireless communication device 1000, the second RFIC 100_1, the modem chip 500, the processor 510, the digital filter of the modem chip 500, the model chip 500_1, the wireless communication device 2000, the first RFIC 200, the second RFIC 201, the third RFIC 202 and/or the modem chip 600 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the buffer circuit of the modem chip 500, a memory of the modem chip 500 storing instructions executable by the processor 510 to perform operations according to embodiments, etc.). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

While the inventive concepts have been particularly shown and described with reference to embodiments thereof, it will be understood that various changes in form and details may be made therein without departing from the spirit and scope of the following claims.

What is claimed is:

1. A radio frequency integrated circuit (RFIC) comprising:
a first receive chain configured to
receive a first high-frequency input signal,
generate a first baseband signal based on the first high-frequency input signal by using a first downward frequency signal, and
output the first baseband signal to a first output port;
a first local oscillator configured to generate a first oscillation clock signal;
a second local oscillator configured to generate a second oscillation clock signal;
a first multiplexer configured to output one among the first oscillation clock signal or the second oscillation clock signal to a second output port based on an oscillation clock output selection signal;
a first input port configured to receive a third oscillation clock signal from an external source; and
a second multiplexer configured to output one among the first oscillation signal, the second oscillation signal or the third oscillation signal to the first receive chain as the first downward frequency signal based on a first downward frequency selection signal.

2. The RFIC of claim 1, further comprising:
a second receive chain configured to
receive a second high-frequency input signal,
generate a second baseband signal based on the second high-frequency input signal by using a second downward frequency signal, and
output the second baseband signal to a third output port; and
a third multiplexer configured to output one among the first oscillation signal, the second oscillation signal or the third oscillation signal to the second receive chain as the second downward frequency signal based on a second downward frequency selection signal.

3. The RFIC of claim 2, wherein the first downward frequency signal has a different frequency than the second downward frequency signal.

4. The RFIC of claim 3, wherein the first oscillation clock signal has a first frequency in a first frequency band, the second oscillation clock signal has a second frequency in a second frequency band, and the third oscillation clock signal has a third frequency in a third frequency band.

5. The RFIC of claim 1, wherein the first receive chain comprises:
a low-noise amplifier configured to amplify the first high-frequency input signal to obtain an amplified first high-frequency input signal; and
a mixer configured to convert the amplified first high-frequency input signal output from the low-noise amplifier into the first baseband signal by using the first downward frequency signal.

6. The RFIC of claim 5, wherein the first receive chain comprises:
a balun between the low-noise amplifier and the mixer.

7. The RFIC of claim 1, wherein the first receive chain comprises:
a low-noise amplifier configured to amplify the first high-frequency input signal to obtain an amplified first high-frequency input signal;
a mixer configured to convert the amplified first high-frequency input signal output from the low-noise amplifier into a baseband analog signal by using the first downward frequency signal; and
an analog-to-digital converter (ADC) configured to convert the baseband analog signal into a digital signal, the digital signal corresponding to the first baseband signal.

8. A wireless communication device comprising:
a first radio frequency integrated circuit (RFIC);
a second RFIC; and
a modem chip,
wherein each of the first RFIC and the second RFIC includes
a first receive chain configured to
receive a first high-frequency input signal,
generate a first baseband signal based on the first high-frequency input signal by using a first downward frequency signal, and
output the first baseband signal to the modem chip through a first output port of the first receive chain,
a second receive chain configured to
receive a second high-frequency input signal,
generate a second baseband signal based on the second high-frequency input signal by using a second downward frequency signal, and
output the second baseband signal to the modem chip through a second output port of the second receive chain,
a first local oscillator configured to generate a first oscillation clock signal,
a second local oscillator configured to generate a second oscillation clock signal,
a first multiplexer configured to output one among the first oscillation clock signal and the second oscillation clock signal to a third output port based on an oscillation clock output selection signal,
a first input port configured to receive a third oscillation clock signal from the modem chip,
a second multiplexer configured to output one among the first oscillation signal, the second oscillation signal or the third oscillation signal to the first receive chain based on a first downward frequency selection signal, and
a third multiplexer configured to output one among the first oscillation signal, the second oscillation signal or the third oscillation signal to the second receive chain based on a second downward frequency selection signal,
the modem chip includes a first oscillation clock input port, a first wire, a first oscillation clock output port, a second oscillation clock input port, a second wire, and a second oscillation clock output port, and
an oscillation clock signal output from the third output port of the first RFIC is input as the third oscillation clock signal to the first input port of the second RFIC through the first oscillation clock input port, the first wire and the first oscillation clock output port.

9. The wireless communication device of claim 8, wherein
an oscillation clock signal output from the third output port of the second RFIC is input as the third oscillation clock signal to the first input port of the first RFIC through the second oscillation clock input port, the second wire and the second oscillation clock output port.

10. The wireless communication device of claim 8, wherein the oscillation clock output selection signal, the first downward frequency selection signal and the second downward frequency selection signal of each of the first RFIC and the second RFIC are set based on at least one control signal of the modem chip.

11. The wireless communication device of claim 10, wherein the at least one control signal of the modem chip is determined according to a carrier aggregation (CA) type.

12. The wireless communication device of claim 8, wherein
the first RFIC, the second RFIC and the modem chip are in a single package; and
each of the first RFIC and the second RFIC is stacked on the modem chip.

13. The wireless communication device of claim 12, wherein
the modem chip comprises at least one through silicon via (TSV) penetrating a substrate, and
each of the first wire and the second wire receives an oscillation clock signal from one of the first RFIC or the second RFIC through the at least one TSV.

14. The wireless communication device of claim 12, wherein
the modem chip further comprises a redistribution layer on a substrate; and
the first wire and the second wire are formed in the redistribution layer.

15. The wireless communication device of claim 8, wherein the third oscillation clock signal input to the first input port of the first RFIC has a third frequency in a third frequency band when:
the first oscillation clock signal of the first RFIC has a first frequency in a first frequency band; and
the second oscillation clock signal of the first RFIC has a second frequency in a second frequency band.

16. The wireless communication device of claim 15, wherein the second local oscillator of the second RFIC is set to generate the second oscillation clock signal having the third frequency when the second local oscillator of the first RFIC is set to generate the second oscillation clock signal having the second frequency.

17. The wireless communication device of claim 8, wherein each of the first baseband signal and the second baseband signal is a digital signal.

18. An operating method of a wireless communication device including a first radio frequency integrated circuit (RFIC), a second RFIC and a modem chip, the operating method comprising:
generating, by the first RFIC, a first oscillation clock signal;
generating, by the second RFIC, a second oscillation clock signal;
outputting, by the second RFIC, the second oscillation clock signal to the modem chip;
outputting, by the modem chip, the second oscillation clock signal to the first RFIC through a wire of the modem chip;
converting, by the first RFIC, a first high-frequency input signal into a first baseband signal by using the first oscillation clock signal; and
converting, by the first RFIC, a second high-frequency input signal into a second baseband signal by using the second oscillation clock signal received from the modem chip, the first RFIC and the second RFIC being stacked on the modem chip.

19. The operating method of claim 18, further comprising:
determining a carrier aggregation (CA) type of the modem chip; and
setting an oscillation clock output selection signal based on the determined CA type, the oscillation clock output selection signal enabling the second RFIC to output the second oscillation clock signal.

20. The operating method of claim 18, wherein the first oscillation clock signal has a different frequency than the second oscillation clock signal.
